(19) United States
(12) Patent Application Publication
(10) Pub. No.: US 2014/0284781 A1
(43) Pub. Date: Sep. 25, 2014

(54) SEMICONDUCTOR MODULE AND MANUFACTURING METHOD THEREOF

(71) Applicant: Kazuya Asaoka, Seto-shi Aichi-ken (JP)

(72) Inventor: Kazuya Asaoka, Seto-shi Aichi-ken (JP)

(73) Assignee: TOYOTA JIDOSHA KABUSHIKI KAISHA, Toyota-shi Aichi-ken (JP)

(21) Appl. No.: 14/218,346

(22) Filed: Mar. 18, 2014

(30) Foreign Application Priority Data
Mar. 22, 2013 (JP) 2013-060434

(51) Int. Cl. H01L 23/495; H01L 23/00

(52) U.S. Cl. CPC H01L 23/49589; H01L 23/49537; H01L 23/562
USPC 257/676; 438/123

(57) ABSTRACT

A first electrode of a first switching element is connected to a first electrode of a second switching element via a first lead frame. A second electrode of the first switching element is connected to an element of a snubber circuit via a second lead frame. A second electrode of the second switching element is connected to the element of the snubber circuit via a third lead frame. A first portion of the element of the snubber circuit is joined to a front face of the second lead frame and a second portion thereof is joined to a front face of the third lead frame. A resin portion has a slit formed to extend from an outer surface of the resin portion to an inside of a gap between opposed end faces of the second lead frame and the third lead frame.

### INCORPORATION BY REFERENCE

The disclosure of Japanese Patent Application No. 2013-060434 filed on Mar. 22, 2013 including the specification, drawings and abstract is incorporated herein by reference in its entirety.

### BACKGROUND OF THE INVENTION

1. Field of the Invention

The present invention relates to a semiconductor module and a manufacturing method thereof.

2. Description of Related Art

Japanese Patent Application Publication No. 2012-115128 (JP 2012-115128 A) describes a resin-sealed semiconductor module in which a snubber circuit is connected in parallel to switching elements. The semiconductor module includes two semiconductor chips (a high-voltage side and a low-voltage side) each including a switching element. One surface of the semiconductor chip on the high-voltage side is connected to the snubber circuit via a first lead frame. One surface of the semiconductor chip on the low-voltage side is connected to the snubber circuit via a second lead frame. A third lead frame is connected to the other surface of the semiconductor chip on the high-voltage side and the other surface of the semiconductor chip on the low-voltage side. According to the technique of JP 2012-115128 A, since the snubber circuit is connected as such, it is possible to reduce in size a loop circuit constituted by the switching elements and the snubber circuit, and even if a high-frequency current flows through this circuit, it is possible to restrain a surge voltage and a radiated noise.

In the technique of JP 2012-115128 A, one end of a ceramic capacitor constituting the snubber circuit is connected to one lead frame, and the other end of the ceramic capacitor is connected to the other lead frame. That is, an element constituting the snubber circuit is provided over two lead frames. According to this configuration, when the element constituting the snubber circuit is sealed by resin, the two lead frames move independently from each other so as to cause stress in a joining portion between the element constituting the snubber circuit and each of the lead frames, which may cause a crack in the joining portions. When a crack occurs in the joining portions, reliability of the semiconductor module decreases.

### SUMMARY OF THE INVENTION

The present invention provides a semiconductor module that restrains a decrease in joining reliability of a joining portion between an element constituting a snubber circuit and a lead frame, and a manufacturing method thereof

A semiconductor module according to a first aspect of the present invention includes a first lead frame, a second lead frame, a third lead frame, a first switching element, a second switching element, a snubber circuit, and a resin portion.

The first switching element includes a first electrode and a second electrode. The second switching element includes a first electrode and a second electrode. The snubber circuit includes at least one element. The resin portion is configured to seal the first lead frame, the second lead frame, the third lead frame, the first switching element, the second switching element, and the snubber circuit. The first electrode of the first switching element is connected to the first electrode of the second switching element via the first lead frame. The second electrode of the first switching element is connected to the element of the snubber circuit via the second lead frame. The second electrode of the second switching element is connected to the element of the snubber circuit via the third lead frame. A first surface of the second lead frame and a first surface of the third lead frame are placed on the same plane. An end face of the second lead frame is opposed to an end face of the third lead frame. A gap is formed between the end face of the second lead frame and the end face of the third lead frame. The element of the snubber circuit is placed over the end face of the second lead frame and the end face of the third lead frame. A first portion of the element of the snubber circuit is joined to the first surface of the second lead frame and a second portion thereof is joined to the first surface of the third lead frame. The resin portion has a slit extending from an outer surface of the resin portion to an inside of the gap between the end face of the second lead frame and the end face of the third lead frame.

Here, the wording “connected via a lead frame” includes not only a case where two members to be connected are directly joined to the lead frame, but also a case where they are connected to the lead frame via other components. Accordingly, a case where one of or both of the two members to be connected are connected to the lead frame via other components (e.g., other lead frames or elements) may be also considered as a state indicated by the wording “connected via a lead frame.”

A manufacturing method of a semiconductor module, according to a second aspect of the present invention, includes a first preparation step, a second preparation step, a lead frame material joining step, a snubber circuit element joining step, a resin portion forming step, and a cutting step. In the first preparation step, a first lead frame is prepared. In the second preparation step, a lead frame material including a connection portion that connects a second lead frame to a third lead frame is prepared. In the lead frame material joining step, a first switching element and a second switching element are joined respectively to that part of the lead frame material which corresponds to the second lead frame and that part of the lead frame material which corresponds to the third lead frame. In the snubber circuit element joining step, an element of a snubber circuit is joined to that part of the lead frame material which corresponds to the second lead frame and that part of the lead frame material which corresponds to the third lead frame. In the resin portion forming step, a resin portion is formed around the element of the snubber circuit and the lead frame material, subsequently to the snubber circuit element junction step. In the cutting step, a slit is formed in the resin portion so as to divide the lead frame material into the second lead frame and the third lead frame, subsequently to the resin portion forming step. According to the manufacturing method, it is possible to restrain a decrease in junction reliability of a joining portion between the lead frame and the element of the snubber circuit.

Details of the aspects of the invention and further improvement thereof are more specifically described in DETAILED DESCRIPTION OF EMBODIMENTS and EXAMPLES.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is a circuit diagram of a semiconductor module of Embodiment 1;

FIG. 2 is a drawing of a longitudinal section of the semiconductor module of Embodiment 1;

FIG. 3 is a plane view to describe a manufacturing method of the semiconductor module of Embodiment 1, and illustrates a lower lead frame;

FIG. 4 is a plane view to describe the manufacturing method of the semiconductor module of Embodiment 1, and illustrates an upper lead frame;

FIG. 5 is a front view to describe the manufacturing method of the semiconductor module of Embodiment 1, and illustrates a state where switching elements are mounted on the lower lead frame;

FIG. 6 is a front view to describe the manufacturing method of the semiconductor module of Embodiment 1, and illustrates a state where a resin portion is formed around the switching elements and the upper lead frame is joined to front faces of the switching elements;

FIG. 7 is a front view to describe the manufacturing method of the semiconductor module of Embodiment 1, and illustrates a state where elements of a snubber circuit are joined to a front face of the lead frame that is joined to the front faces of the switching elements;

FIG. 8 is a plane view of FIG. 7;

FIG. 9 is a front view to describe the manufacturing method of the semiconductor module of Embodiment 1, and illustrates a state where a resin portion is formed around the elements of the snubber circuit, the upper lead frame, and the lower lead frame;

FIG. 10 is a perspective view to describe the manufacturing method of the semiconductor module of Embodiment 1, and illustrates a state where resin is filled in slits of the lower lead frame and gaps of the upper lead frame;

FIG. 11 is a perspective view to describe the manufacturing method of the semiconductor module of Embodiment 1, and illustrates a state where slits are formed to cut an upper lead frame material; and

FIG. 12 is a drawing of a longitudinal section of a semiconductor module of Embodiment 2.

### DETAILED DESCRIPTION OF EMBODIMENTS

Main features of embodiments to be described below are listed. Note that technical elements to be described below are technical elements independent from each other and each exhibit a technical usability solely or in various combinations.

A semiconductor module of an embodiment of the present invention may be configured such that a first electrode of a first switching element and a first electrode of a second switching element are joined onto a first surface of a first lead frame. The first surface of the first lead frame may be opposed to a second surface of a second lead frame and a second surface of a third lead frame, and the first lead frame may have a slit connected to a slit of a resin portion. According to the above configuration, after the resin portion is formed in a state where a slit according to a slit to be formed in the resin portion is formed in the first lead frame, it is possible to form the slit in the resin portion along the slit formed in the first lead frame. Since the slit is formed in the resin portion along the slit thus formed in advance in the first lead frame, it is possible to easily form the slit at a desired position in the resin portion in comparison with a case where the slit is not formed in advance in the first lead frame.

In the semiconductor module of the embodiment of the present invention, no slit may be formed in a part of the first lead frame which is opposed to an element of a snubber circuit. According to the above configuration, when the slit is formed in the resin portion along the slit formed in advance in the first lead frame, it is possible to restrain the element of the snubber circuit from being cut.

In the semiconductor module of the embodiment of the present invention, a thickness of the first lead frame may be larger than each of a thickness of the second lead frame and a thickness of the third lead frame. When the slit is formed in the resin portion, resin is filled in the slit of the first lead frame. The first lead frame is formed from a material having a cutting strength higher than that of the resin. In view of this, it is possible to form the slit in the resin portion in such a manner that the resin is cut by means of a cutting tool along a boundary between the resin filled in the slit of the first lead frame and the first lead frame. At this time, since the thickness of the first lead frame is larger than the thicknesses of the second and third lead frames, it is possible to cut the resin portion by a cutting force by which the second and third lead frames are cut but the first lead frame is not cut. This makes it possible to restrain the cutting tool from forming the slit in the resin portion beyond the slit of the first lead frame. Thus, it is possible to form the slit in the resin portion appropriately by using, as a guide, the slit formed in the first lead frame.

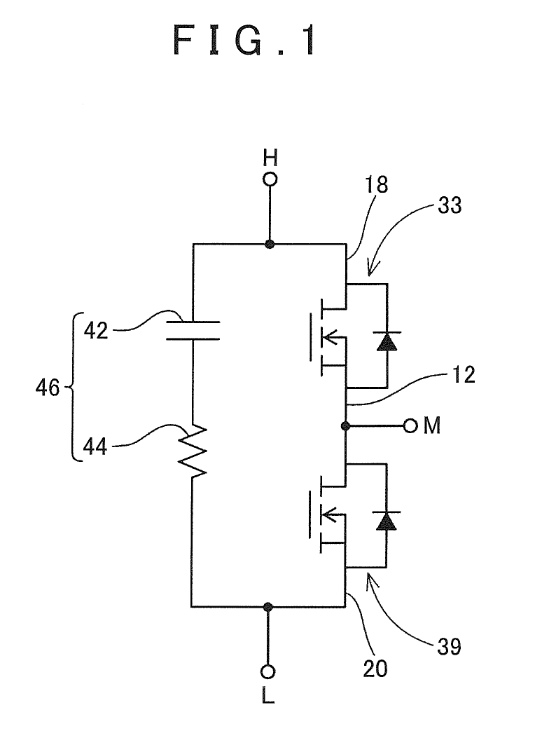

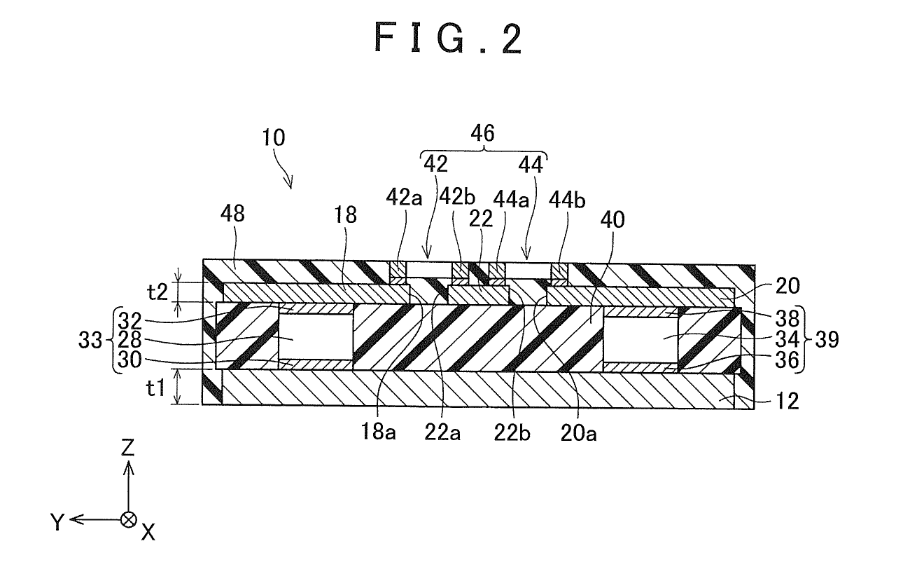

A semiconductor module 10 of the present embodiment is described with reference to FIGS. 1, 2. FIG. 1 is a circuit diagram of the semiconductor module 10, and is a circuit diagram for one phase of a motor driving inverter circuit provided in a hybrid vehicle. As illustrated in FIG. 1, in this circuit, two switching elements 33, 39 are connected to each other in series. In each of the switching elements 33, 39, a reflux diode connected thereto in a reverse parallel manner is formed integrally. In the present embodiment, the switching element 33 is connected to a connecting terminal H on a high-voltage side, and the switching element 39 is connected to a connecting terminal L on a low-voltage side. A connecting point between the switching element 33 and the switching element 39 is connected to an output terminal M. A snubber circuit 46 constituted by a series connection of a capacitor 42 and a resistor 44 is connected in parallel to the two switching elements 33, 39. The snubber circuit 46 absorbs a surge voltage to be caused in the switching elements when the switching elements are turned off.

A three-phase inverter circuit is configured by bridge-connecting three sets of a series connection constituted by the two switching elements 33, 39 (that is, the semiconductor module of FIG. 1). In the present embodiment, an n-type MOSFET using a SiC substrate as a switching element is used. By forming a MOSFET in a SiC substrate, a reflux diode is formed integrally with the SiC substrate. The switching elements 33, 39 constituting an inverter circuit, and the snubber circuit 46 for protecting them are incorporated in the semiconductor module 10. Note that the switching element 33 may be considered as an example of the “first switching element.” Further, the switching element 39 may be considered as an example of the “second switching element.”

FIG. 2 is a drawing of a longitudinal section of the semiconductor module 10. The two switching elements 33, 39 are mounted on a front face (a surface perpendicular to a Z-direction) of a lower lead frame 12. The switching elements 33, 39 have generally the same configuration, but are reversed to each other in the Z-direction. More specifically, the switching element 33 is constituted by a SiC substrate 28, a drain electrode 32 formed on a front face of the SiC substrate 28, and a source electrode 30 formed on a rear face of the SiC substrate 28. In the meantime, the switching element 39 is constituted by a SiC substrate 34, a source electrode 38 formed on a front face of the SiC substrate 34, and a drain electrode 36 formed on a rear face of the SiC substrate 34. A semiconductor device structure (including a gate electrode) is formed in the SiC substrates 28, 34. Since the semiconductor device structure formed in the SiC substrates 28, 34 is well known conventionally, details thereof are omitted. The source electrode 30 of the switching element 33 and the drain electrode 36 of the switching element 39 are joined by soldering to the front face of the lower lead frame 12. That is, the source electrode 30 of the switching element 33 is connected to the drain electrode 36 of the switching element 39 via the lower lead frame 12. Note that the source electrode 30 of the switching element 33 may be considered as an example of the “first electrode of the first switching element.” The drain electrode 36 of the switching element 39 may be considered as an example of the “first electrode of the second switching element.”

In the present embodiment, a resin portion 40 is formed around the switching elements 33, 39. A front face of the resin portion 40 is placed at generally the same height as a front face of the drain electrode 32 of the switching element 33 and a front face of the source electrode 38 of the switching element 39. The resin portion 40 is formed of resin having high heat conductivity.

Three lead frames are joined to the front face of the drain electrode 32, the front face of the source electrode 38, and the front face of the resin portion 40. In the following description, the three lead frames are referred to as an upper-left lead frame 18, an upper-intermediate lead frame 22, and an upper-right lead frame 20, sequentially from a Y-direction side. The lead frames 18, 20, 22 have generally the same thickness. In view of this, front faces (surfaces perpendicular to the Z-direction) of the upper-left lead frame 18, the upper-right lead frame 20, and the upper-intermediate lead frame 22 are placed on the same plane. Rear faces (surfaces perpendicular to the −Z-direction) of the lead frames 18, 20, 22 are opposed to the front face of the lower lead frame 12. A thickness t2 of the lead frames 18, 20, 22 is smaller than a thickness t1 of the lower lead frame 12. Note that the drain electrode 32 of the switching element 33 may be considered as an example of a “second electrode of the first switching element.” The source electrode 38 of the switching element 39 may be considered as an example of a “second electrode of the second switching element.”

Elements of the snubber circuit 46 are mounted on the front faces of the lead frames 18, 20, 22. In the present embodiment, the snubber circuit 46 is constituted by the capacitor 42 and the resistor 44. A ceramic capacitor is used as the capacitor 42. However, the capacitor 42 is not limited to this, and a film capacitor may be used, for example. Further, a chip resistor is used as the resistor 44, but the resistor 44 is not limited to this.

First of all, the following describes mounting of the capacitor 42. As illustrated in FIG. 2, a gap is formed between an end face 18a of the upper-left lead frame 18 on a −Y-direction side and an end face 22a of the upper-intermediate lead frame 22 on a Y-direction side, and the end faces 18a, 22a are opposed to each other. The capacitor 42 is disposed over between the end face 18a and the end face 22a. More specifically, one electrode 42a of the capacitor 42 is soldered to the front face of the upper-left lead frame 18, and the other electrode 42b of the capacitor 42 is soldered to the front face of the upper-intermediate lead frame 22. Hereby, the drain electrode 32 of the switching element 33 is connected to the capacitor 42 via the upper-left lead frame 18. Further, as will be described later, the source electrode 38 of the switching element 39 is connected to the capacitor 42 via the upper-right lead frame 20, the resistor 44, and the upper-intermediate lead frame 22. Accordingly, in a case where the capacitor 42 is considered as an example of an “element of the snubber circuit,” the upper-left lead frame 18 may be considered as an example of the “second lead frame,” and the upper-intermediate lead frame 22 may be considered as an example of the “third lead frame.” Further, the one electrode 42a of the capacitor 42 may be considered as an example of a “first portion of the element of the snubber circuit,” and the other electrode 42b may be considered as an example of a “second portion of the element of the snubber circuit.”

Next will be described mounting of the resistor 44. As illustrated in FIG. 2, a gap is formed between an end face 22b of the upper-intermediate lead frame 22 on a −Y-direction side and an end face 20a of the upper-right lead frame 20 on a Y-direction side, and the end faces 22b, 20a are opposed to each other. The resistor 44 is disposed over between the end face 22b and the end face 20a. More specifically, one end 44a of the resistor 44 is soldered to the front face of the upper-intermediate lead frame 22, and the other end 44b of the resistor 44 is soldered to the front face of the upper-right lead frame 20. Hereby, the source electrode 38 of the switching element 39 is connected to the resistor 44 via the upper-right lead frame 20. Further, the one end 44a of the resistor 44 is connected to the other electrode 42b of the capacitor 42 via the upper-intermediate lead frame 22. As a result, the drain electrode 32 of the switching element 33 is connected to the resistor 44 via the upper-left lead frame 18, the capacitor 42, and the upper-intermediate lead frame 22. Note that, in a case where the resistor 44 is considered as an example of the “element of the snubber circuit,” the upper-intermediate lead frame 22 may be considered as an example of the “second lead frame,” and the upper-right lead frame 20 may be considered as an example of the “third lead frame.” Here, in a case where the capacitor 42 is considered as an example of the “element of the snubber circuit,” the upper-intermediate lead frame 22 may be considered as an example of the “third lead frame”. In a case where the resistor 44 is considered as an example of the “element of the snubber circuit,” the upper-intermediate lead frame 22 may be considered as an example of the “second lead frame.” Further, the one end 44a of the resistor 44 may be considered as an example of the “first portion of the element of the snubber circuit,” and the other end 44b may be considered as an example of the “second portion of the element of the snubber circuit.”

The lower lead frame 12, the resin portion 40, the upper lead frames 18, 20, 22, the capacitor 42, and the resistor 44 are integrally resin-sealed by a resin portion 48. At this time, the sealing is performed such that a terminal of the lower lead frame 12, a terminal of the upper-left lead frame 18, and a terminal of the upper-right lead frame 20 are exposed outside the resin portion 48.

The upper-left lead frame 18 is joined to the drain electrode 32 of the switching element 33. A connecting terminal H of the upper-left lead frame 18 is connected to a high-voltage power supply via a wiring line. In the meantime, the upper-right lead frame 20 is joined to the source electrode 38 of the switching element 39. A connecting terminal L of the upper-right lead frame 20 is connected to a low-voltage power supply via a wiring line. The lower lead frame 12 is joined to the source electrode 30 of the switching element 33 and the drain electrode 36 of the switching element 39. The source electrode 30 and the drain electrode 36 have an intermediate potential between the high-voltage power supply and the low-voltage power supply of the inverter circuit. A connecting terminal M of the lower lead frame 12 is connected to any of a U phase, a V phase, and a W phase of an AC motor (not shown) via a wiring line.

In the semiconductor module 10 having the above layout, it is possible to place the elements 42, 44 constituting the snubber circuit 46 in vicinity of the switching elements 33, 39. In view of this, an excessive surge voltage to be caused at the time when the switching elements 33, 39 are turned off is absorbed by the elements 42, 44 of the snubber circuit 46 appropriately. Accordingly, even if a semiconductor element that enables fast switching, such as SiC-MOS, is used as the switching elements 33, 39, it is possible to restrain a voltage larger than withstanding voltages of the switching elements and peripheral components from being added to these elements and components, at the time when the switching elements are turned off

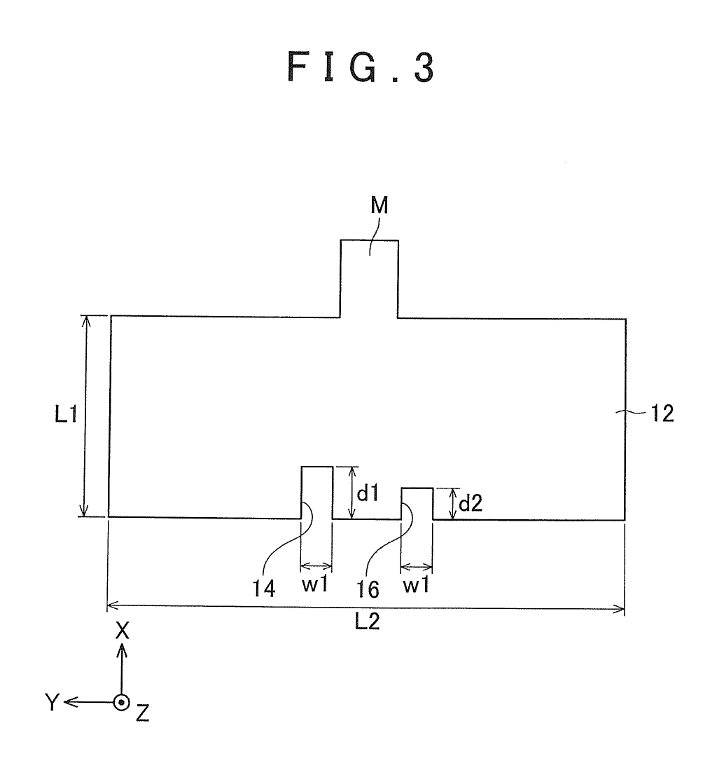

Next will be described a manufacturing method of the semiconductor module 10 with reference to FIGS. 3 to 11. The following describes a part related to the embodiment of the present invention in detail, and descriptions about the other parts are omitted because they are well known conventionally. In the present embodiment, the semiconductor module 10 is manufactured by performing a lower lead frame preparation step, an upper lead frame preparation step, a switching element mounting step, a first resin portion forming step, an upper lead frame joining step, a snubber circuit element joining step, a second resin portion forming step, and an upper lead frame cutting step.

The following describes the lower lead frame preparation step. First of all, a lower lead frame 12 is prepared as illustrated in FIG. 3. The lower lead frame 12 is a lead frame having a generally rectangular shape in which a short side is L1 and a long side is L2, and two slits 14, 16 are formed in one long side (a side of two sides extending along the Y direction, the side provided on a −X-direction side). The slit 14 is a rectangular slit having a width (a length in the Y-direction) of w1 and a depth (a length in the X-direction) of d1. The slit 16 is a rectangular slit having a width of w1 and a depth of d2. The depths d1, d2 have a relationship of d1>d2. The slits 14, 16 are formed with a given distance therebetween generally in a center of the long side of the lower lead frame 12. A connection terminal M is formed in the other long side (a side of the two sides extending along the Y-direction, the side provided on an X-direction side) of the lower lead frame 12. In the present embodiment, copper alloy is used for the lower lead frame 12, but the lower lead frame 12 is not limited to this, and iron alloy may be used, for example.

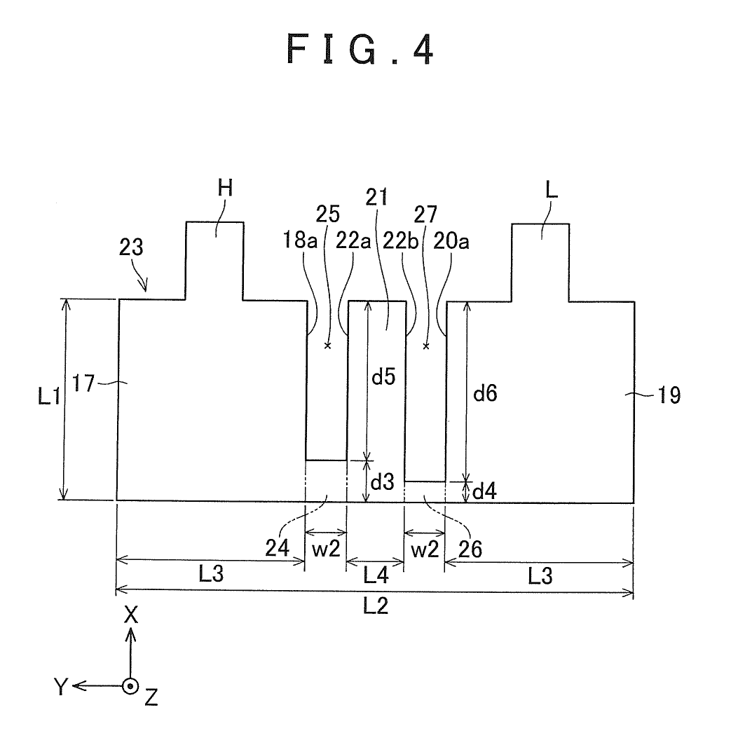

The following describes the upper lead frame preparation step. As illustrated in FIG. 4, an upper lead frame 23 is prepared. The upper lead frame 23 is a lead frame having a generally rectangular shape in which a short side is L1 and a long side is L2 (that is, generally the same shape as the lower lead frame 12), and two gaps 25, 27 are formed in one long side (a side of two sides extending along the Y-direction, the side provided on an X-direction side). The gap 25 is a rectangular gap having a width of w2 and a depth of d5, and the gap 27 is a rectangular gap having a width of w2 and a depth of d6. The depths d5, d6 have a relationship of d5<d6. In the one long side of the upper lead frame 23, connecting terminals H, L are formed, respectively, on a Y-direction side relative to the gap 25 and on a −Y-direction side relative to the gap 27. When a part of the lower lead frame 12 except the connecting terminal M and a part of the upper lead frame 23 except the connecting terminals H, L are opposed to each other in the Z-direction and viewed in a plane manner from the Z-direction, the gap 25 is formed so that that center line of the gap 25 which extends in the X-direction is placed on the same straight line as that central line of the slit 14 which extends in the X-direction. Similarly, the gap 27 is formed so that that center line of the gap 27 which extends in the X-direction is placed on the same straight line as that central line of the slit 16 which extends in the X-direction.

A shape of the upper lead frame 23 can be described as follows. That is, the upper lead frame 23 has a shape in which three sub lead frames 17, 21, 19 are connected by connection portions 24, 26. More specifically, the sub lead frame 17 has a long side having a length of L1 and a short side having a length of L3. A long side thereof on a −Y-direction side has an end face 18a formed perpendicularly (in. a −Z-direction) from the long side. In the meantime, the sub lead frame 21 has a long side having a length of L1 and a short side having a length of L4, and a long side thereof on a Y-direction side has an end face 22a formed perpendicularly (in the −Z-direction) from the long side. End portions of the end faces 18a, 22a on a −X-direction side are connected to each other by the connection portion 24. The connection portion 24 has a rectangular shape. The connection portion 24 has a width of w2 and a depth of d3. Similarly, the sub lead frame 19 has a long side having a length of L1 and a short side having a length of L3, and has an end face 20a formed perpendicularly (in the −Z-direction) from a long side on a Y-direction side. In the meantime, the sub lead frame 21 has an end face 22b formed perpendicularly (in the -Z-direction) from a long side on a −Y-direction side. End portions of the end faces 20a, 21b on a −X-direction side are connected to each other by the connection portion 26. The connection portion 26 has a rectangular shape. The connection portion 26 has a width of w2 and a depth of d4. The depths d3, d4 have a relationship of d3>d4. Further, a relationship of d3+d5=d4+d6=L1 and a relationship of 2L3+L4+2w2=L2 are established.

The end face 18a is opposed to the end face 22a in the Y-direction, and the end face 20a is opposed to the end face 22b in the Y-direction. Accordingly, it may be considered that the gap 25 is formed between the end face 18a and the end face 22a, and the gap 27 is formed between the end face 20a and the end face 22b.

Those central lines of the connection portions 24, 26 which extend in the X-direction are placed on the same straight lines as the central lines of the gaps 25, 27, respectively. In view of this, those central lines of the connection portions 24, 26 which extend in the X-direction are placed on the same straight lines as those central lines of the slits 14, 16 of the lower lead frame 12 which extend in the X-direction, respectively. Further, a relationship of w2>w1 is established between the width w2 of the connection portions 24, 26 and the width w1 of the slits 14, 16, and relationships of d3<d1, d4<d2 are established between the depths d3, d4 of the connection portions 24, 26 and the depths d1, d2 of the slits 14, 16. As will be described in detail later, part of each of the connection portions 24, 26 in FIG. 4 is cut in the X-direction in a later step. Hereby, the upper lead frame 23 is divided into three lead frames. The three lead frames are an upper-left lead frame 18, an upper-intermediate lead frame 22, and an upper-right lead frame 20, sequentially from the Y-direction. In the present embodiment, copper alloy is used for the upper lead frame 23, but the upper lead frame 23 is not limited to this, and iron alloy may be used, for example. Note that the upper lead frame 23 may be considered as an example of a “lead frame material.”

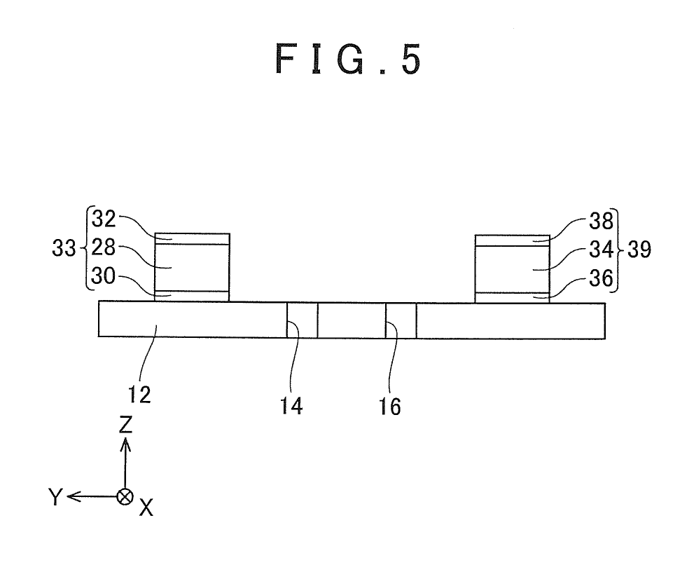

The following describes the switching element mounting step. As illustrated in FIG. 5, switching elements 33, 39 are mounted on a front face of the lower lead frame 12. A source electrode 30 of the switching element 33 and a drain electrode 36 of the switching element 39 are joined to the front face of the lower lead frame 12. The switching element 33 is mounted closer to the Y-direction side than the slit 14, and the switching element 39 is mounted closer to the −Y-direction side than the slit 16. Hereby, the source electrode 30 of the switching element 33 is connected to the drain electrode 36 of the switching element 39 via the lower lead frame 12.

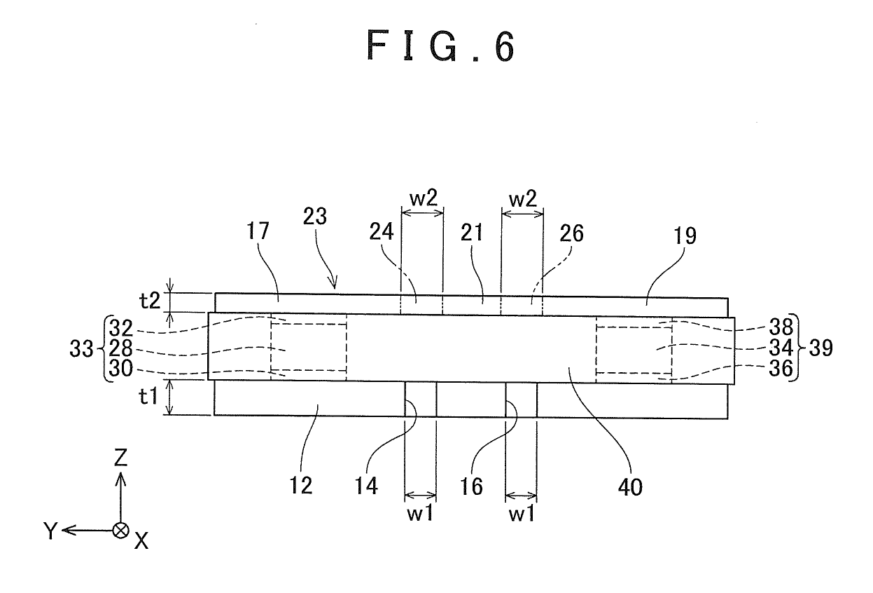

The following describes the first resin portion forming step and the upper lead frame joining step. As illustrated in FIG. 6, a resin portion 40 is formed around the switching elements 33, 39, and then, the upper lead frame 23 is joined to respective electrodes 32, 38 of the switching elements 33, 39. In FIG. 6, the switching elements 33, 39 sealed by the resin portion 40 are shown in a broken line. In the present embodiment, the resin portion 40 is formed by performing press work on a thermosetting resin sheet by use of a press apparatus. Since a method for molding the resin portion 40 by press work is a conventionally well-known method, a description thereof is omitted. The resin portion 40 is formed so that its front face is placed at generally the same height as a front face of the drain electrode 32 of the switching element 33 and a front face of the source electrode 38 of the switching element 39. It is preferable that resin having a high heat conductivity be used for the resin sheet. Note that a formation method of the resin portion 40 is not limited to the press work, and other methods may be used.

When the resin portion 40 is formed, the upper lead frame 23 is joined to the front faces of the drain electrode 32, the source electrode 38, and the resin portion 40. At this time, the switching elements 33, 39 are sealed and fixed by the resin portion 40, so that it is restrained that stress occurs in respective joining portions between the lower lead frame 12 and the switching elements 33, 39. Since the switching elements 33, 39 have generally the same dimension, a rear face of the upper lead frame 23 is opposed to the front face of the lower lead frame 12 generally in parallel therewith. In FIG. 6, the connection portions 24, 26 of the upper lead frame 23 are shown in an alternate long and two short dashes line. The connection portions 24, 26 are opposed to the slits 14, 16 in the Z-direction, respectively. Further, a relationship of t1>t2 is established between the thickness t1 of the lower lead frame 12 and the thickness t2 of the upper lead frame 23.

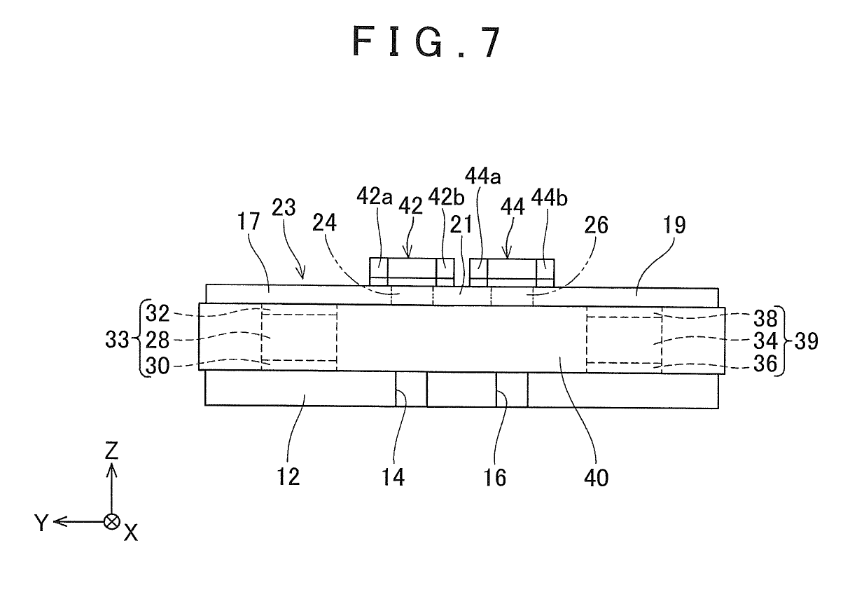

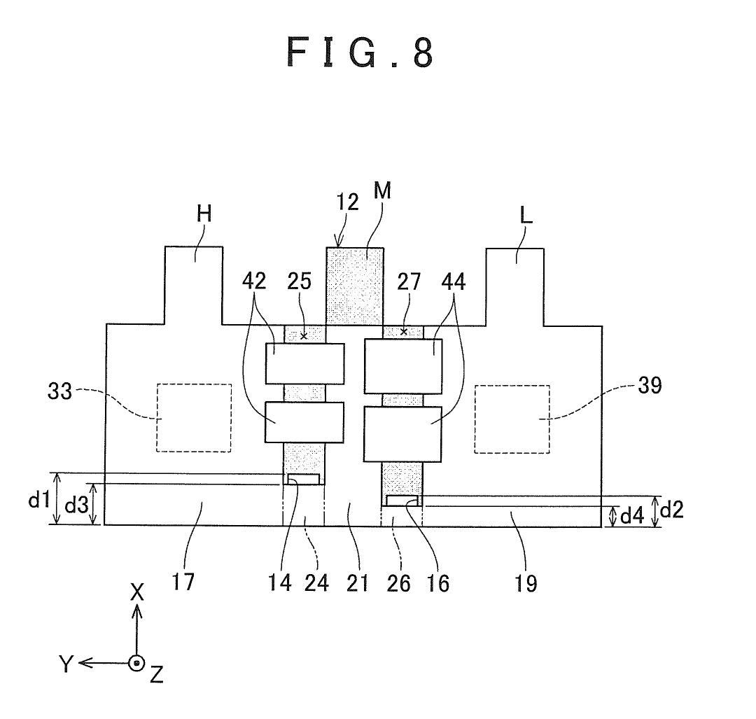

The following describes the snubber circuit element joining step. As illustrated in FIGS. 7, 8, capacitors 42 and resistors 44 are joined to a front face of the upper lead frame 23. The switching elements 33, 39 are shown in a broken line in FIGS. 7, 8. Further, in FIG. 8, illustration of the resin portion 40 is omitted and a dot pattern is added to the front face of the lower lead frame 12. The capacitors 42 are joined over the gap 25. That is, one electrodes 42a of the capacitors 42 are soldered to the sub lead frame 17 and the other electrodes 42b thereof are soldered to the sub lead frame 21, so that the capacitors 42 are joined to the front face of the upper lead frame 23. As illustrated in FIG. 8, two capacitors 42 are connected in parallel in the present embodiment, but the number of capacitors to be joined is not limited to this and may be one, or three or more. Similarly, the resistors 44 are joined over the gap 27. That is, one ends 44a of the resistors 44 are soldered to the sub lead frame 21 and the other ends 44b thereof are soldered to the sub lead frame 19, so that the resistors 44 are joined to the front face of the upper lead frame 23. As illustrated in FIG. 8, two resistors 44 are connected in parallel in the present embodiment, but the number of resistors to be joined is not limited to this and may be one, or three or more.

As illustrated in FIG. 8, when the front face of the upper lead frame 23 is viewed in a plane manner, end portions of the slits 14, 16 in the X-direction are respectively placed within the gaps 25, 27 of the upper lead frame 23 beyond the connection portions 24, 26 due to d1>d3, d2>d4. Further, positions of the capacitors 42 are adjusted so that the capacitors 42 are not opposed to the slit 14 in the Z-direction. Similarly, positions of the resistors 44 are adjusted so that the resistors 44 are not opposed to the slit 16 in the Z-direction. In other words, the slits 14, 16 are not formed at those positions in the lower lead frame 12 which are opposed to the capacitors 42 and the resistors 44 in the Z-direction. A snubber circuit 46 is constituted by the capacitors 42 and the resistors 44.

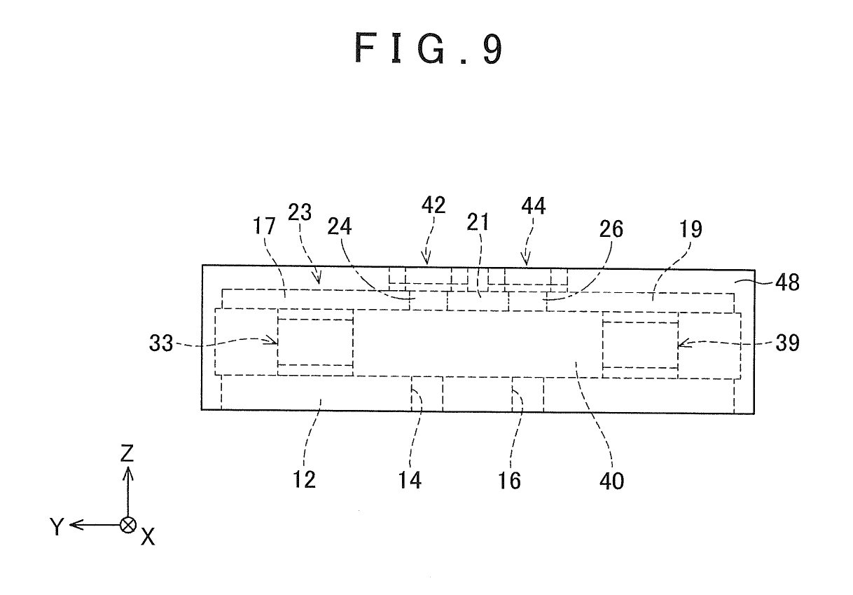

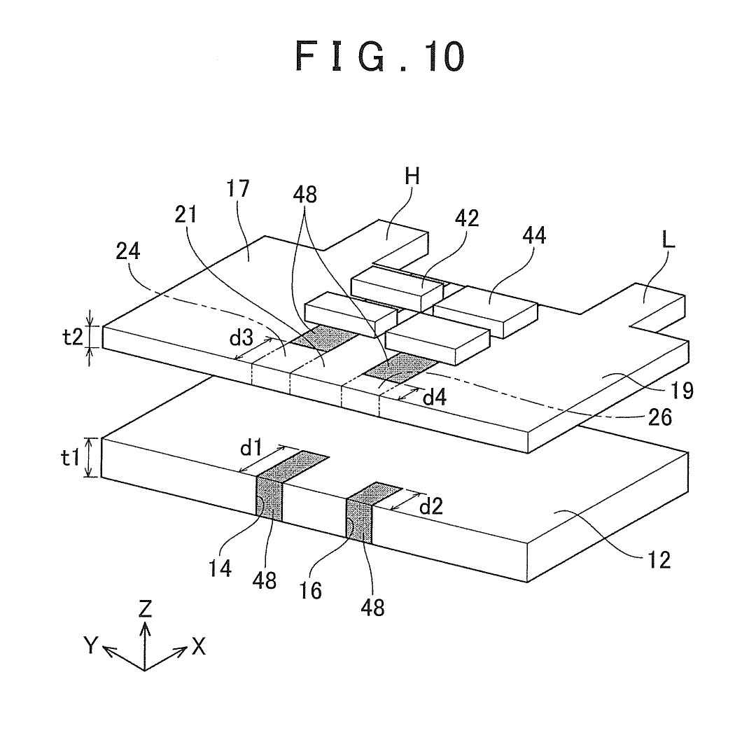

The following describes the second resin portion forming step. As illustrated in FIG. 9, thermosetting resin is injection-molded so as to integrally seal, by a resin portion 48, the lower lead frame 12, the resin portion 40, the upper lead frame 23, the capacitors 42, and the resistors 44. In FIG. 9, the members thus sealed are shown in a broken line, and the connection portions 24, 26 are shown in an alternate long and two short dashes line. Hereby, the capacitors 42 and the resistors 44 are fixed to the upper lead frame 23. A method of the injection molding is conventionally well known, and therefore descriptions thereof are omitted. An epoxy resin is used, for example, as the thermosetting resin, but the thermosetting resin is not limited to this. FIG. 10 is a perspective view of a state in which the resin portion 48 is formed. For simplicity of FIG. 10, illustrations of the resin portion 40 (including the switching elements 33, 39) and the resin portion 48, the resin portion 48 covering outer surfaces and side surfaces of the upper lead frame 23 and the lower lead frame 12, are omitted. The resin portion 48 formed by injection molding is filled in the slits 14, 16 of the lower lead frame 12, and the gaps 25, 27 of the upper lead frame 23. Note that the sealing is performed such that the connection terminal M of the lower lead frame 12 and the connection terminals H, L of the upper lead frame 23 are exposed outside the resin portion 48. Note that the second resin portion forming step may be considered as an example of a “resin portion forming step.”

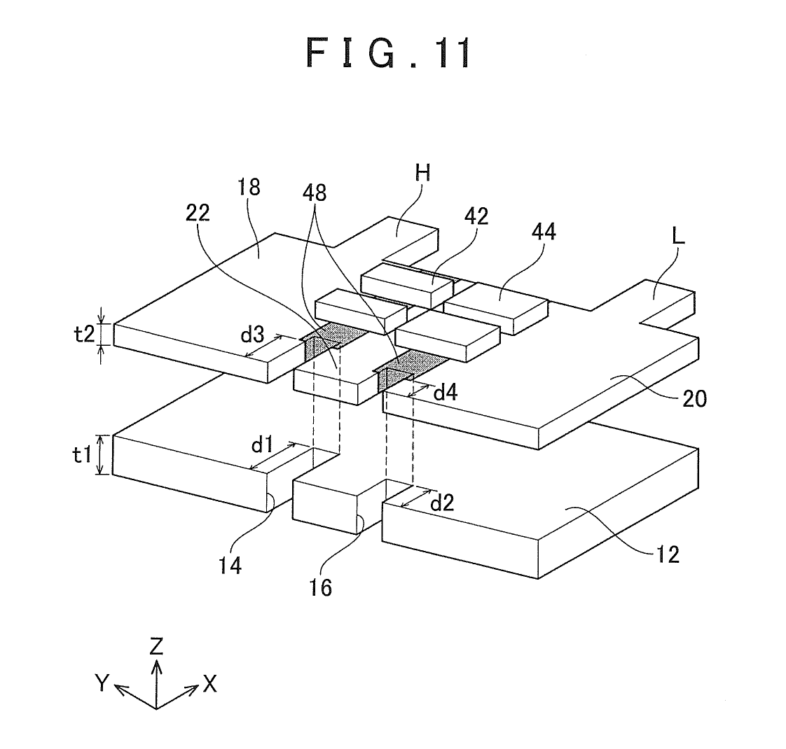

The following describes the upper lead frame cutting step. As illustrated in FIG. 11, the connection portions 24, 26 of the upper lead frame 23 are partially cut, so as to cut the upper lead frame 23 into three lead frames. More specifically, the resin portion 48 filled in the slit 14 is cut along a boundary between the lower lead frame 12 and the resin portion 48 filled in the slit 14 of the lower lead frame 12 (that is, along a shape of the slit 14). A cutting tool such as a cutter is used for the cutting. The cutter is inserted generally vertically to that end face out of end faces of the upper lead frame 23 where the connection portions 24, 26 are formed, and to that end face out of end faces of the lower lead frame 12 where the slits 14, 16 are formed, so as to simultaneously cut the resin portion 48 filled in the slit 14 and the upper lead frame 23. The connection portion 24 is formed at a position opposed to the slit 14 in the Z-direction and the depth d1 of the slit 14 is larger than the depth d3 of the connection portion 24. In view of this, when the cutting is performed in the aforementioned manner, a slit having generally the same dimension as the slit 14 is formed in the connection portion 24 (and the resin portion 48 filled in the gap 25), and thus, the connection portion 24 is cut. At this time, since the width w2 of the connection portion 24 is larger than the width w1 of the slit 14, part of the connection portion 24 remains without being cut, strictly speaking.

When the resin portion 48 filled in the slit 16 is cut along a shape of the slit 16 in the same manner as above, part of the connection portion 26 is cut. Hereby, the upper lead frame 23 is divided into an upper-left lead frame 18, an upper-intermediate lead frame 22, and an upper-right lead frame 20, sequentially from the Y-direction. That is, the capacitors 42 are joined over two different lead frames, i.e., the upper-left lead frame 18 and the upper-intermediate lead frame 22, and the resistors 44 are joined over two different lead frames, i.e., the upper-right lead frame 20 and the upper-intermediate lead frame 22.

Note that the upper-left lead frame 18 has a shape in which that part of the connection portion 24 which is not cut is attached to the sub lead frame 17. In view of this, it may be said that the upper-left lead frame 18 has the end face 18a of the sub lead frame 17. Similarly, the upper-right lead frame 20 has a shape in which that part of the connection portion 26 which is not cut is attached to the sub lead frame 19, so that the upper-right lead frame 20 has the end face 20a. The upper-intermediate lead frame 22 has a shape in which those parts of the connection portions 24, 26 which are not cut are attached to the sub lead frame 21, so that the upper-intermediate lead frame 22 has the end faces 22a, 22b.

According to the manufacturing method described above, it is possible to manufacture the semiconductor module 10 of the present embodiment as illustrated in FIG. 2. As is apparent from the above description, in the resin portion 48 of the semiconductor module 10, slits are formed so as to extend from an outer surface of the resin portion 48 respectively to the gap 25 formed between the end face 18a of the upper-left lead frame 18 and the end face 22a of the upper-intermediate lead frame 22, and to the gap 27 formed between the end face 20a of the upper-right lead frame 20 and the end face 22b of the upper-intermediate lead frame 22.

According to this manufacturing method, when the resin portion 48 is formed, the lead frames 18, 20, 22 are connected to each other so as to form one upper lead frame 23. This restrains respective lead frames from moving independently at the time of resin molding, in comparison with a case where the respective lead frames are not connected when a resin portion is formed. Accordingly, it is possible to restrain such a case that stress occurs in respective joining portions between the upper lead frame 23 and the electrodes 42a, 42b of the capacitors 42 at the time of resin molding, thereby making it possible to restrain occurrence of cracks in the joining portions. The same can be true to respective joining portions between the upper lead frame 23 and both ends of the resistors 44. Further, the lead frames 18, 20, 22 are connected to each other at the time of joining the capacitors 42 and the resistors 44 thereto. In view of this, it is possible to restrain respective lead frames from moving independently at the time of joining these elements thereto, thereby making it possible to restrain stress from occurring in respective joining portions between the upper lead frame 23 and the elements 42, 44. By manufacturing the semiconductor module 10 by such a method, it is possible to restrain a decrease in joining reliability of the upper lead frame 23 with respect to the capacitors 42 and the resistors 44.

Further, in the present embodiment, the slits 14, 16 are formed in the lower lead frame 12, and the resin filled in the slits 14, 16 is cut along the shapes of the slits, so that the upper lead frame 23 is divided into three lead frames. Generally, a cut resistance of the resin is largely lower than a cut resistance of the lead frame. In view of this, in comparison with a case where the upper lead frame 23 is cut without forming a slit in the lower lead frame 12 (that is, the lower lead frame 12 is cut together), the cut resistance decreases, thereby making it possible to easily cut the upper lead frame 23. Further, by cutting the upper lead frame 23 along the slits 14, 16, the slits 14, 16 function as a guide at the time of the cutting. This makes it possible to restrain a dimension of a slit to be formed in the upper lead frame 23 from varying among products of the semiconductor module.

Further, in the present embodiment, the slits 14, 16 are not founed at those positions in the lower lead frame 12 which are opposed to the capacitors 42 and the resistors 44. This makes it possible to restrain such a case that a cutting tool cuts the capacitors 42 or the 44 by mistake, when the connection portions 24, 26 of the upper lead frames 23 are cut along the shapes of the slits 14, 16.

Further, in the present embodiment, the lower lead frame 12 is thicker than the upper lead frame 23. When the cutting tool makes contact with that surface (e.g., a surface of the slit 14 in YZ directions) out of a surface constituting the slits 14, 16 which intersects with a moving direction of the cutting tool, the cutting tool makes contact with the lower lead frame 12 having a cut resistance larger than that of the resin portion 48. Here, since the thickness of the lower lead frame 12 is larger than that of the upper lead frame 23, the cut resistance increases as compared with a cut resistance at the time of cutting the resin in the slits 14, 16 and the upper lead frame 23. By providing, in the cutting tool, a sensor for detecting a cut resistance, a cutting speed, or the like, it is possible to control the cutting tool so as to stop the cutting in the moving direction at the time when the cut resistance increases. Hereby, since the lower lead frame 12 functions as a trigger for stopping the cutting by the cutting tool, it is possible to restrain the cutting tool from cutting the lower lead frame 12 to deviate from the shapes of the slits 14, 16. Accordingly, it is possible to surely restrain the cutting tool from cutting the capacitors 42 or the resistors 44 by mistake.

Further, according to this manufacturing method, it is possible to form the connection portions 24, 26 in relatively vicinity to the capacitors 42 and the resistors 44. In view of this, in comparison with a case where the connection portions are formed at positions apart from these elements, it is possible to largely reduce stress to be applied to the joining portions between the upper lead frame 23 and these elements at the time of joining or resin sealing.

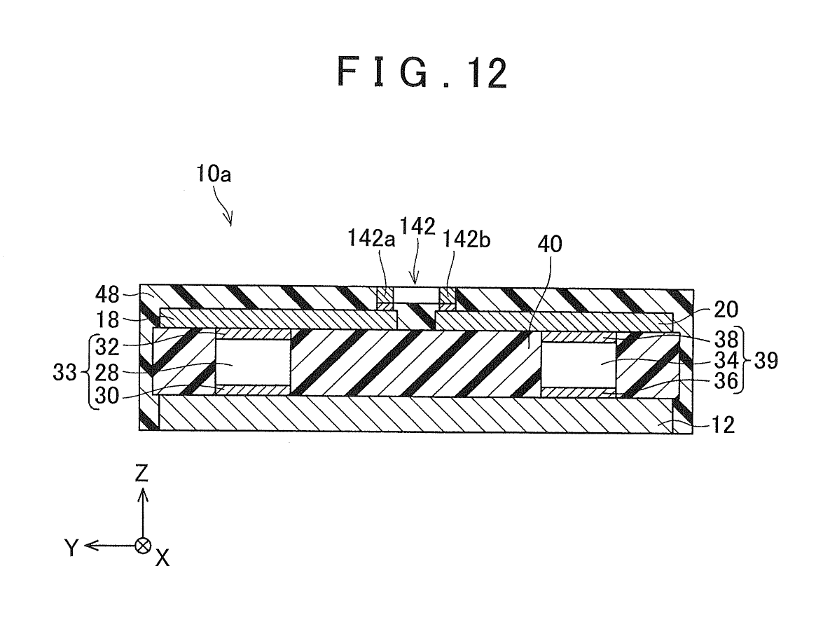

Next will describe Embodiment 2 with reference to FIG. 12. The following deals with only a point different from Embodiment 1, and detailed descriptions thereof about the same configuration as Embodiment 1 are omitted.

A semiconductor module 10a of Embodiment 2 is different from the semiconductor module 10 of Embodiment 1 in the following point. That is, a snubber circuit 46 is constituted by a capacitor 142. Further, no upper-intermediate lead frame 22 is formed. In the semiconductor module 10a, an upper-left lead frame 18 may be considered as an example of the “second lead frame,” and an upper-right lead frame 20 may be considered as an example of the “third lead frame.”

The semiconductor module 10a is manufactured by a method similar to the method for manufacturing the semiconductor module 10 of Embodiment 1 until the upper lead frame joining step. Note that the number of slits formed in a lower lead frame 12 is one, and the number of gaps (accordingly, the number of connection portions) formed between the upper lead frames (18, 20) is also one. Although not illustrated in FIG. 12, the slit of the lower lead frame 12 is opposed to the connection portion of the upper lead frames (18, 20) in a Z-direction. In a snubber circuit element joining step, the capacitor 142 is joined over a gap between the upper lead frames (18, 20). In a second resin portion forming step, a resin portion 48 is formed in the same manner as in Embodiment 1. In an upper lead frame joining step, the connection portion of the upper lead frames (18, 20) is cut along the slit formed in the lower lead frame 12. Hereby, electrodes 142a, 142b of the capacitor 142 are joined to two different lead frames 18, 20, respectively. The semiconductor module 10a manufactured by the above method yields the same effect as the semiconductor module 10 of Embodiment 1. Further, since the number of cutting portion in the upper lead frame cutting step is one, it is possible to improve manufacture efficiency of the semiconductor module 10a.

In the semiconductor module of the above embodiment, the element of the snubber circuit is disposed over the second lead frame and the third lead frame, and the slit is formed in the resin portion at a position between the second lead frame and the third lead frame. In the semiconductor module of the above embodiment, a lead frame material in which the second lead frame and the third lead frame are connected at a position corresponding to the slit of the resin portion is prepared, the resin portion is formed after the element of the snubber circuit is joined to the lead frame material. Subsequently, the slit is formed in the resin portion so as to cut the lead frame material cut into the second lead frame and the third lead frame. This accordingly makes it possible to connect the second lead frame and the third lead frame at the time of forming the resin portion, thereby making it possible to restrain stress from occurring in the joining portion between the lead frame and the element of the snubber circuit. Since the semiconductor module can be manufacture by the above method, it is possible to restrain a decrease in junction reliability of the joining portion between the lead frame and the element of the snubber circuit.

Embodiments of the present invention have been described in detail, but these are only examples, and the semiconductor module of the present invention and the manufacturing method thereof include embodiments obtained by variously modifying or altering the above embodiments.

For example; in the above embodiments, an n-type MOSFET is used as the switching element, but IGBT or RC-IGBT may be used. Further, a p-type MOSFET may be used. Further, a material of a substrate constituting the switching element is not limited to SiC, and Si may be used, for example.

Further, the lower lead frame 12, the switching elements 33, 39, the upper lead frame 23, the capacitors 42, and the resistors 44 may be integrally sealed by the resin portion 48 without forming the resin portion 40. Further, in the above embodiments, since a dimension of the resistors 44 is larger than a dimension of the capacitors 42, the relationships of d1>d2, d3>d4 are established. However, if relationships of d1≧d3, d2≧d4 are established, a magnitude relationship between d1 and d2 and a magnitude relationship between d3 and d4 (that is, d5 and d6) are not limited particularly. Further, in the above embodiments, the relationship of w1<w2 is established, but a relationship of w1=w2 may be established. At this time, it is preferable that the central lines of the slits 14, 16 in the X-direction and the central lines of the connection portions 24, 26 in the X-direction be placed on the same straight lines, respectively, when the upper lead frame is viewed in a plane manner. Further, the connection portions may be formed at three or more portions. Further, it is not necessary that the terminals of the lead frames be arranged in one direction, and they may be arranged in different directions.

Further, the manufacturing method of the semiconductor module of the present invention can be applied to not only an element constituting a snubber circuit, but also other electronic components. Further, the semiconductor module of the present invention may be used for an electric vehicle as well as a hybrid vehicle.

Concrete embodiments of the invention have been described in detail, but these embodiments are only examples and do not limit the invention according to Claims. The present invention includes embodiments obtained by variously modifying or altering the concrete embodiments exemplified as above. Further, technical elements described in the present specification or the drawings exhibit a technical usability solely or in various combinations. Further, the technique exemplified in the present specification or the drawings can achieve a plurality of objects at the same time, and has a technical usability by achieving one of those objects.

What is claimed is:

1. A semiconductor module comprising:
a first lead frame;
a second lead frame;
a third lead frame;
a first switching element including a first electrode and a second electrode;
a second switching element including a first electrode and a second electrode;
a snubber circuit including at least one element; and
a resin portion configured to seal the first lead frame, the second lead frame, the third lead frame, the first switching element, the second switching element, and the snubber circuit, wherein:
the first electrode of the first switching element is connected to the first electrode of the second switching element via the first lead frame;
the second electrode of the first switching element is connected to the element of the snubber circuit via the second lead frame;
the second electrode of the second switching element is connected to the element of the snubber circuit via the third lead frame;
a first surface of the second lead frame and a first surface of the third lead frame are placed on a same plane;
an end face of the second lead frame is opposed to an end face of the third lead frame;
a first gap is formed between the end face of the second lead frame and the end face of the third lead frame;
the element of the snubber circuit is placed over the end face of the second lead frame and the end face of the third lead frame;
a first portion of the element of the snubber circuit is joined to the first surface of the second lead frame and a second portion of the element of the snubber circuit is joined to the first surface of the third lead frame; and
the resin portion has a slit extending from an outer surface of the resin portion to an inside of the first gap between the end face of the second lead frame and the end face of the third lead frame.

2. The semiconductor module according to claim 1, wherein:
the first electrode of the first switching element and the first electrode of the second switching element are joined onto a first surface of the first lead frame;
the first surface of the first lead frame is opposed to a second surface of the second lead frame and a second surface of the third lead frame; and
the first lead frame has a slit connected to the slit of the resin portion.

3. The semiconductor module according to claim 2, wherein
no slit is formed in a part of the first lead frame which is opposed to the element of the snubber circuit.

4. The semiconductor module according to claim 2, wherein
a thickness of the first lead frame is larger than each of a thickness of the second lead frame and a thickness of the third lead frame.

5. The semiconductor module according to claim 2, wherein:
a second gap is formed between the end face of the second lead frame and the end face of the third lead frame;
a width of the second gap in a direction perpendicular to a stacking direction of the first lead frame and the second lead frame is not more than a width of the slit of the first lead frame; and
the second gap is opposed to the slit of the first lead frame in the stacking direction.

6. The semiconductor module according to claim 1, wherein:
the first electrode of the first switching element and the first electrode of the second switching element are joined onto a first surface of the first lead frame;
the first surface of the first lead frame is opposed to a second surface of the second lead frame and a second surface of the third lead frame;
a second gap is formed between the end face of the second lead frame and the end face of the third lead frame;
a width of the second gap in a direction perpendicular to a stacking direction of the first lead frame and the second lead frame is not more than a width of the first gap; and
the second gap is opposed to the slit of the first lead frame in the stacking direction.

7. The semiconductor module according to claim 6, wherein
the width of the second gap in the direction perpendicular to the stacking direction of the first lead frame and the second lead frame is the same as that of the slit of the resin portion.

8. A manufacturing method of a semiconductor module, comprising:
a first preparation step of preparing a first lead frame;
a second preparation step of preparing a lead frame material including a connection portion that connects a second lead frame to a third lead frame;
a switching element mounting step of mounting a first switching element and a second switching element on the first lead frame;
a lead frame material joining step of joining the first switching element and the second switching element respectively to a part of the lead frame material which corresponds to the second lead frame and a part of the lead frame material which corresponds to the third lead frame;
a snubber circuit element joining step of joining an element of a snubber circuit to the part of the lead frame material which corresponds to the second lead frame and the part of the lead frame material which corresponds to the third lead frame;
a resin portion forming step of, subsequently to the snubber circuit element joining step, forming a resin portion around the element of the snubber circuit and the lead frame material; and
a cutting step of, subsequently to the resin portion forming step, forming a slit in the resin portion so as to divide the lead frame material into the second lead frame and the third lead frame.

9. The manufacturing method according to claim 8, wherein
in the first preparation step, a slit is formed in a part of the first lead frame which is opposed, after the lead frame material joining step, to the connection portion in a stacking direction of the first lead frame and the lead frame material.

10. The manufacturing method according to claim 9, wherein
in the snubber circuit element joining step, the element of the snubber circuit is joined so as to be opposed, in the stacking direction, to a part of the first lead frame which includes no slit.
